(19) United States
(12) Patent Application Publication
(10) Pub. No.: US 2020/0098674 A1
(43) Pub. Date: Mar. 26, 2020

(54) PACKAGE EDGE MOUNTED FRAME STRUCTURES

(71) Applicant: Intel Corporation, Santa Clara, CA (US)

(72) Inventors: Chin Lee Kuan, Bentong (MY); Amit Kumar Jain, Portland, OR (US); Sameer Shekhar, Portland, OR (US)

(73) Assignee: Intel Corporation, Santa Clara, CA (US)

(21) Appl. No.: 16/142,249

(22) Filed: Sep. 26, 2018

(51) Int. Cl. H01L 23/498; H01L 25/065; H01L 23/00; H01L 21/48

(52) U.S. Cl. CPC H01L 23/49805; H01L 23/49816; H01L 25/0657; H01L 23/49866; H01L 24/16; H01L 2225/06548; H01L 2224/16225; H01L 2225/06517; H01L 2225/06586; H01L 2225/06551; H01L 21/4853

(57) ABSTRACT

Embodiments may relate to a semiconductor package. A conductive frame may be coupled with the semiconductor package. The conductive frame may include a first portion, a second portion, and a third portion positioned between the first portion and the second portion. The first portion may be coupled with the first side of the semiconductor package. The second portion may be coupled with the second side of the semiconductor package. The third portion may be coupled with the sidewall of the semiconductor package. Other embodiments may be described or claimed.

### BACKGROUND

Some semiconductor packages may suffer from a high-power or performance penalty due to high load line (impedance) from an onboard voltage regulator to loads on a die of the semiconductor package. These penalties may be particularly pronounced in small form factor, Z height constrained, or cost constrained semiconductor packages. For example, some legacy semiconductor packages may have a 15 milli-ohm (mΩ) load line with an estimated 150 (millivolt) mV performance degradation.

### BRIEF DESCRIPTION OF THE DRAWINGS

FIG. 1 depicts an example system, in accordance with various embodiments.

FIG. 2 depicts a simplified example side view of a semiconductor package, in accordance with various embodiments.

FIG. 3 depicts a simplified top-down view of a semiconductor package, in accordance with various embodiments.

FIG. 4 depicts a simplified bottom view of a semiconductor package, in accordance with various embodiments.

FIG. 5 depicts a simplified bottom view of an alternative example semiconductor package, in accordance with various embodiments.

FIG. 6 depicts a simplified example side view of a portion of a semiconductor package, in accordance with various embodiments.

FIG. 7 depicts an example technique for the manufacture of a semiconductor package, in accordance with various embodiments.

FIG. 8 illustrates an example device that may use various embodiments herein, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise.

Generally, embodiments herein may improve direct current (DC) resistance and alternating current (AC) loop of voltage rail power delivery from a voltage regulator to multiple loads on a die of a package. Specifically, some embodiments may include a low resistance frame of an electrically conductive material such as copper. The frame may be coupled to the edge of the semiconductor package. Embodiments may further include a composite structure to address power delivery in packages that include multiple voltage rails. Embodiments may further include a high-k dielectric material encapsulated in the conductive frame to increase passive capacitance of the frame. Some embodiments may include discrete capacitors coupled with the frame exterior.

Generally, various embodiments may help reduce the above-described parasitic impedance. As a result, embodiments may provide significant performance gains for semiconductor packages, for example by increasing central processing unit (CPU) core or graphics performance. Additionally, embodiments may reduce one or more size factors of the semiconductor package such as Z height or overall lateral area of the package. Some embodiments may further reduce the cost of a semiconductor package. Additionally, some embodiments may enable single-sided platform assembly due to a reduced capacitance requirement.

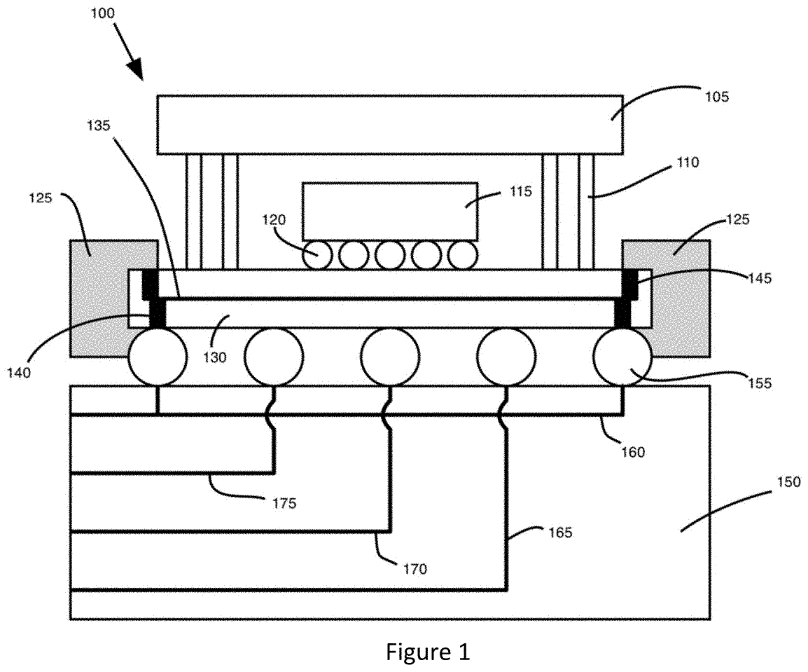

FIG. 1 depicts an example system 100, in accordance with various embodiments. Specifically, the system 100 may include a semiconductor package that includes a substrate 130 with the power rail 135. The substrate 130 may be, for example a cored or coreless substrate that may include a plurality of conductive elements such as traces or vias. The power rail 135 may be, for example, a conductive trace within the substrate 130 that is designed to carry power to or from various elements of the semiconductor package, or elements coupled with the semiconductor package. The semiconductor package may further include a die 115 coupled with the substrate 130 by a plurality of electrical interconnects 120. The die 115 may be, for example, a processing unit, a memory, or some other type of die. For example, if die 115 is a memory, the memory may be a dynamic random-access memory (DRAM), a static random-access memory (SRAM), a non-volatile memory (NVM), or some other type of memory. If die 115 as a processing unit, the processing unit may be a CPU, a general processing unit (GPU), a single or multi-core processor, or some other type of processing unit. It will be understood that although die 115 as depicted is a singular die, in some embodiments the die 115 may be replaced by a plurality of dies coupled to one another by micro bumps or micro vias.

The electrical interconnects 120 may be, for example, solder bumps, plated elements of a redistribution layer, or some other type of electrical interconnect. More generally, the electrical interconnects 120 may be configured to carry data signals or power between the die 115 and the substrate 130. The electrical interconnects 120 may be, for example, coupled with one or more vias, traces, or some other conductive element within the substrate 130, or along the top surface of the substrate 130. These additional elements are not shown for the sake of clarity of the Figure.

The semiconductor package may further include one or more additional dies such as die 105. Die 105 may be a die such as a memory, processing unit, or some other type of die such as those described above with respect to die 115. The die 105 may be coupled with the substrate 130 by additional electrical interconnects 110. The electrical interconnects 110 may be, for example, a pillar formed of a conductive material such as copper. In other embodiments, the electrical interconnects 110 may be solder bumps, or some other type of electrical interconnect.

The package may be coupled with a substrate 150 by electrical interconnects 155. Similarly to electrical interconnects 120, electrical interconnects 155 may be solder bumps, plated interconnects of a redistribution layer, or some other type of electrical interconnect. The substrate 150 may be, for example, a motherboard, or some other type of substrate. More generally, the substrate 150 may be a cored or coreless substrate with a plurality of conductive elements such as traces or vias positioned therein.

The substrate 150 may include a plurality of rails, which may be similar to power rail 135. Specifically, rail 160 may be a first power rail, which may be referred to as VCC1. Rail 175 may be another power rail, which may be referred to as VCC2. Rail 170 may be, for example, a ground rail which may be referred to as VSS. Rail 165 may be a signal rail which may be designed to carry communicative signals between the semiconductor package and another element coupled with the substrate 150. It will be understood that the depictions of the number of rails and the substrate 150, and the specific description of what each rail is, is intended only as one example embodiment. In other embodiments the substrate 150 may include more or fewer rails, or specific rails may be used for other functions. For example, in some embodiments the substrate may include four rails, but only one of those rails may be a power rail, and three of the rails may be signal rails. Other variations may be present in other embodiments. It will further be understood that in some embodiments one or more of the rails, for example the power rails, may be coupled with a voltage regulator that is coupled with, or is an element of, the substrate 150.

The system 100 may further include a conductive frame 125 around the periphery of the substrate 130. More specifically, the conductive frame 125 may be coupled with the sidewall of the substrate 130, which may be considered to be the portion of the substrate 130 at the periphery of the substrate 130 and positioned between the top surface and the bottom surface of the substrate 130. Generally, the conductive frame 125 may be formed of a conductive material such as copper or some other conductive material. As can be seen in FIG. 1, the conductive frame 125 may surround both the periphery of the substrate 130, as well as be coupled to both the top side and the bottom side of the substrate as oriented in FIG. 1. In embodiments, the conductive frame 125 may be coupled with the top side of the substrate 130 by TIM material such as thermal adhesive. Additionally, the conductive frame 125 may be coupled with the bottom side of the substrate 130 by a solder material such as that which may be used in electrical interconnects 155, or some other material.

In embodiments, the power rail 135 of the substrate 130 may be coupled with a rail of the substrate 150 by one or more of the electrical interconnects 155 as shown in FIG. 1. Specifically, the power rail 135 may be coupled with a via 140 in the substrate 130, which is in turn coupled with an electrical interconnect 155 that is coupled with the rail 160. The via 140 may be, for example, a through silicon via (TSV), a plated via, or some other type of via. Generally, the via 140 may be referred to as a “micro-via.” The via 140 may allow communication between the electrical interconnect 155 and the power rail 135.

In these embodiments, the conductive frame 125 may additionally be coupled with the power rail 135, as shown in FIG. 1. Specifically, the conductive frame 125 may be electrically and physically (e.g., mechanically) coupled with one or more of the electrical interconnects 155. Additionally, the substrate 130 may include a top side via 145, which may be similar to via 140. The conductive frame 125 may be coupled with the via 145. Therefore, in these embodiments, the conductive frame 125 may be coupled with the power rail 135 through both the top side and the bottom side of the substrate 130. In other embodiments, the conductive frame 125 may only be coupled with the power rail 135 through either the via 145 or the via 140.

It will be understood that FIG. 1 is intended as a highly simplified example of a system 100, and additional elements may be omitted from the Figure for the sake of clarity and reduction of clutter. For example, although only one power rail 135 is depicted as an element of substrate 130, in other embodiments the substrate 130 may have a plurality of power rails, each of which coupled with a different one of the rails 160/165/170/175 through electrical interconnects 155. Additionally, one or more of the power rails may be coupled with one or both of the dies 115 or 105 through electrical interconnects 120 or 110. Additionally, although only a certain number of elements such as dies 105/115, electrical interconnects 110/120/155, or rails 160/165/170/175 are depicted in FIG. 1, in other embodiments a system may have a greater or lesser number of elements than are shown in FIG. 1.

The system 100 may realize one or more of the benefits above due at least in part to the conductive frame 125. Specifically, the conductive frame 125 may provide multiple low resistance parallel paths for current flow from the voltage regulator to the dies 115/105. As a result, the multiple low resistance parallel paths for current flow may reduce the overall parasitic impedance experienced by the system 100. This reduced parasitic impedance may be due at least in part to the conductive frame having a low resistance due to a relatively thick amount of conductive material, as will be discussed below. As a result, the dies 105 or 115 may experience significantly increased performance capabilities.

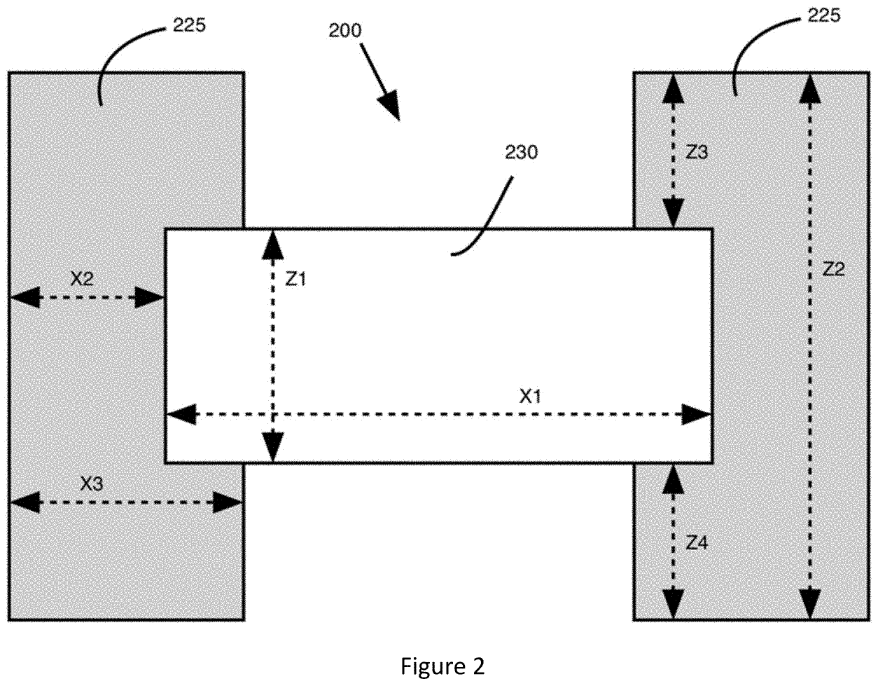

FIG. 2 depicts a simplified example side view of a semiconductor package 200, in accordance with various embodiments. Specifically, the semiconductor package 200 may include a substrate 230 surrounded by a conductive frame 225, which may be respectively similar to substrate 130 and conductive frame 125. The various additional elements of the semiconductor package 200 such as those described above with respect to the semiconductor package of FIG. 1, are omitted from FIG. 2 for the sake of clarity of the Figure. Rather, FIG. 2 is intended to assist with discussion of various dimensions of the semiconductor package 200. It will, however, be understood that FIG. 2 may not be drawn to scale so that the various dimensions may be properly illustrated and annotated for the sake of discussion.

Generally, the substrate 230 may have a Z height dimension Z1 and a lateral dimension X1. In some embodiments, the dimension X1 may be, for example, on the order of approximately 20 millimeters (mm). The dimension Z1 may be, for example, on the order of approximately 200 micrometers (“microns” or “μm”).

The conductive frame 225 may have an overall Z height Z2 of approximately 600 μm. Specifically, the conductive frame 225 may measure approximately 200 μm from the top of the substrate 230, as indicated by Z3. The conductive ring 225 may also measure approximately 200 μm from the bottom of the substrate 230, as indicated by Z4.

Additionally, the conductive frame 225 may have an overall width, as indicated by X3, of approximately 500 μm. In this embodiment, the portion of the conductive frame 225 that is at the periphery of the substrate 230 may measure approximately 200 μm as indicated by X2. In this embodiment, the conductive frame 225 may then overlap the substrate 230 by approximately 300 μm.

It will be understood, however, that the above-described measurements are intended as examples. In other embodiments, the conductive frame 225 or the substrate 230 may have different measurements in one or more dimension. For example, the conductive frame 225 may have a different measurement in the lateral dimension or the Z height dimension than is depicted in FIG. 2. Similarly, the substrate 230 may have a different measurement in the lateral dimension or the Z height dimension than is depicted in FIG. 2. Generally, the conductive frame 225 may have a Z height between approximately 300 μm and a millimeter. The conductive frame 225 may have a measurement in the lateral dimension on the order of hundreds of microns. Similarly, the substrate 230 may generally have a measurement in the lateral dimension on the order of tens of millimeters, and a measurement in the Z height dimension on the order of tens of microns. Therefore, based on these various dimensions, it will be understood that the above-described advantages that the system 100 may experience based at least in part on the conductive frame 125 may be achieved without appreciable additional package size in the lateral dimension or the Z height dimension.

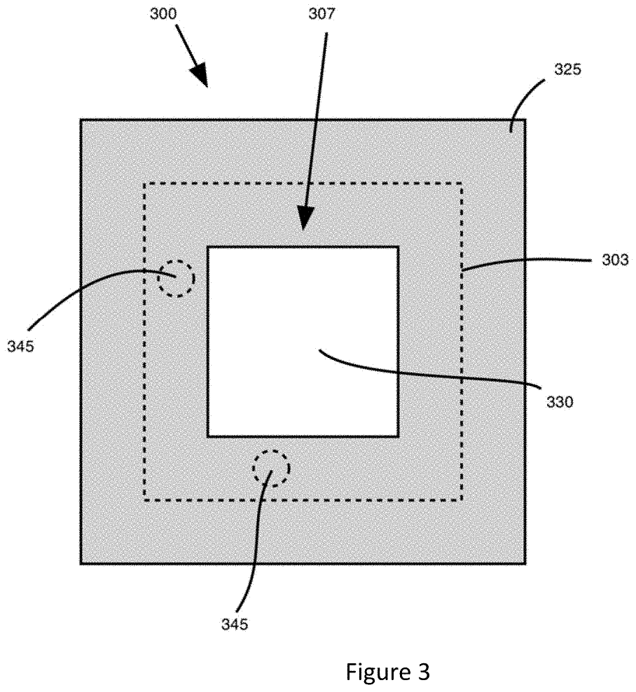

FIG. 3 depicts a simplified top-down view of a semiconductor package 300, in accordance with various embodiments. The semiconductor package 300 may be similar to the semiconductor package discussed above with respect to FIG. 1. Specifically, the semiconductor package 300 may include a conductive frame 325 and a substrate 330, which may be respectively similar to conductive frame 125 and substrate 130. It will be understood that semiconductor package 300 may include additional elements depicted in FIG. 1, for example dies 105 or 115, electrical interconnects 110 or 120, etc. However, those additional elements may not be depicted in FIG. 3 for the sake of clarity and elimination of clutter within the Figure.

The periphery of the substrate 330 may be indicated by dashed line 303, which is overlapped by conductive frame 325 is discussed above with respect to FIG. 2. As can be seen in FIG. 3, in embodiments the top side of the substrate 330 may be exposed by an opening 307 in the conductive frame 325.

The substrate 330 may additionally include one or more vias 345 which may be similar to vias 145. As can be seen in FIG. 3, the vias 345 may be within the periphery of the substrate 330 as indicated by dashed line 303, but overlapped by the conductive frame 325. In this manner, the conductive frame 325 may be coupled with a power rail of the substrate 330 such as power rail 135 described above.

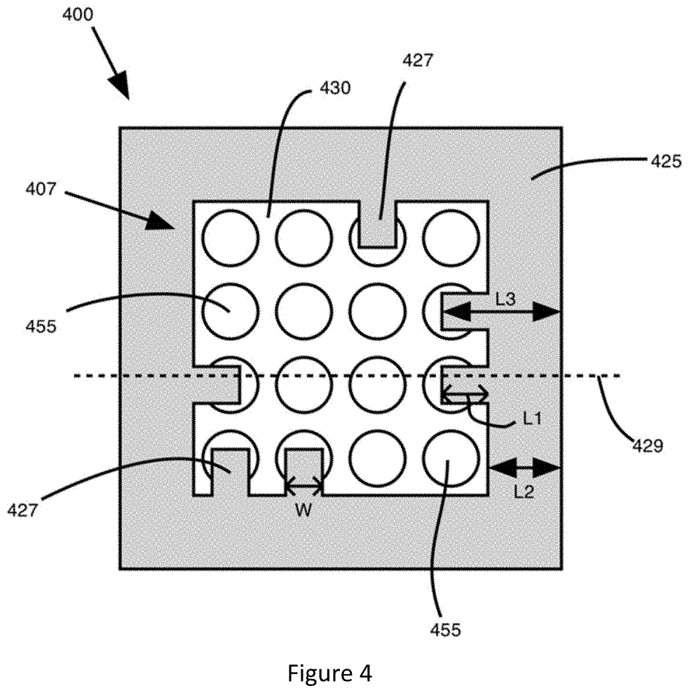

FIG. 4 depicts a simplified bottom view of a semiconductor package 400, in accordance with various embodiments. The semiconductor package 400 may be similar to the semiconductor package described above with respect to FIG. 1. Specifically, the semiconductor package 400 may include a substrate 430 and a conductive frame 425, which may be respectively similar to substrate 130 and conductive frame 125. The substrate 430 may be coupled with a plurality of electrical interconnects 455, which may be similar to electrical interconnects 155. The conductive frame 425 may include an opening 407, which may be similar to opening 307. Specifically, the substrate 430 may be exposed by the opening 407.

The conductive frame 425 may include a plurality of fingers 427, which are coupled with the electrical interconnects 455. Specifically, the embodiment of FIG. 1 that shows the conductive frame coupled with the electrical interconnects 155 and the vias 140 may be considered to be a cross-sectional depiction along the line 429 depicted in FIG. 4. In some embodiments, the body of the conductive frame 425 may at least partially overlap the substrate 430, for example as depicted above with respect to FIG. 3. In other embodiments, only the fingers 427 may overlap the substrate 430.

As can be seen in FIG. 4, the conductive frame 400 may include fingers on a plurality of sides of the opening 407. Generally, the fingers may have a length L1 of approximately 300 μm as discussed above. More specifically, the length of the conductive frame 425 inclusive of the fingers 427 may be approximately 500 μm as indicated by dimension L3. The length of the conductive frame 425 exclusive of the fingers 427, as indicated by L2, may be approximately 200 μm. Additionally, the fingers may have a width W of approximately 200 μm. However, as noted above, it will be understood that these dimensions are intended as examples of one embodiment, and other embodiments may have one or more dimensions that are larger or smaller than discussed above with respect to FIG. 3 or 4. For example, one or more of the dimensions discussed herein may be different based on factors such as estimated impedance of the various load lines, the specific function of one or more dies of the semiconductor package, the floor plan or height requirements of the overall system or the semiconductor package, or some other factor.

As shown in FIG. 4, some embodiments may have one or more fingers 427 on each of the sides of the opening 407, while in other embodiments one or more of the sides of the opening 407 may not have a finger. In some embodiments, each of the fingers 427 may be coupled with the respective electrical interconnect 455 as shown in FIG. 4, while in other embodiments a finger 427 may be coupled with a plurality of the electrical interconnects 455. In some embodiments one or more of the fingers 427 may be electrically decoupled from another one of the fingers 427. Therefore, one of the fingers 427 may be electrically coupled to one of the rails 160/165/170/175 of FIG. 1, while another one of the fingers 427 may be coupled with a different one of the rails 160/165/170/175. Additionally, although the fingers 427 are depicted as being coupled with an electrical interconnect 455 that is closest to it, in other embodiments one or more of the fingers 427 may be physically coupled with, but electrically decoupled from, a close electrical interconnect, and be electrically coupled with an interconnect that is further from it.

Generally, it will be understood that the semiconductor package 400 of FIG. 4 is intended as one example, and other embodiments may have one or more elements in a different configuration, or may include a greater or lesser number of elements than are depicted in FIG. 4. For example, in some embodiments the substrate 430 may have a number of electrical interconnects 455 on the order of hundreds, thousands, or millions of electrical interconnects 455. Additionally, even though only six fingers 427 are depicted in FIG. 4, other embodiments may have a greater or lesser number of fingers 427.

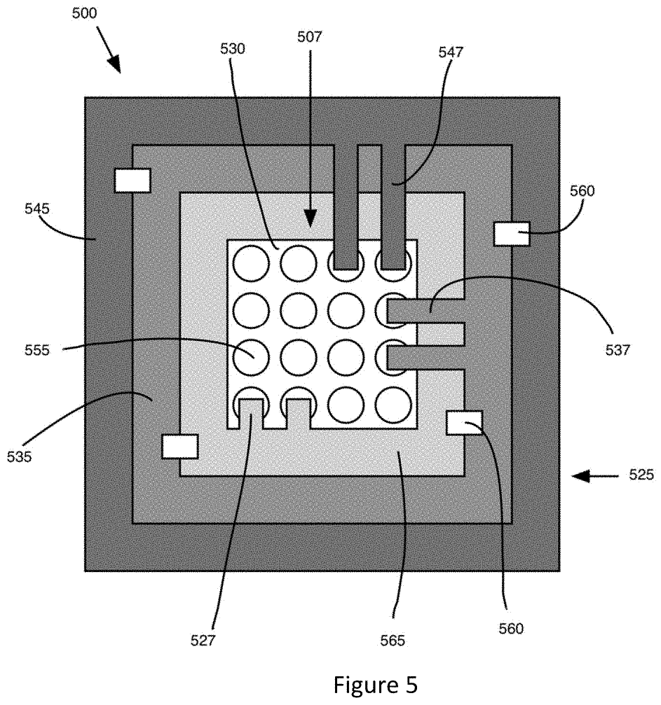

As noted above, one or more of the fingers may be electrically decoupled from another one of the fingers. In this embodiment, one finger may be communicatively coupled with one of the rails 160/165/170/175 while another finger is communicatively coupled with another one of the rails 160/165/170/175. FIG. 5 depicts one example semiconductor package 500 that may address two voltage rail (e.g., VCC1 and VCC2) power delivery. It will be understood that although the embodiment of FIG. 5 is a highly simplified example to depict one embodiment which may address this power delivery, the concepts depicted by the embodiment of FIG. 5 may be scaled to address a higher number of rails. For products like essential segments (e.g., entry-level microprocessor market segments), the embodiment of FIG. 5 may be used for core or graphics power rail (GT) type of power rails with a potential load line reduction of approximately 25% for both rails. As noted above, embodiments may only require a minimal design area, may be designed to not interfere with signal breakouts, and may have little to no height penalty (as may exist with increased numbers of layers), thereby keeping the package form factor competitive from a cost and size perspective.

Specifically, FIG. 5 may depict a semiconductor package 500. The semiconductor package 500 may include a substrate 530 with a plurality of electrical interconnects 555, which may be respectively similar to substrate 130 and electrical interconnects 155. The semiconductor package 500 may further include a conductive frame 525 with an opening 507, which may be similar to conductive frames 125 or 425 and opening 407. Specifically, the conductive frame 525 may be formed of a conductive material such as copper or some other conductive material.

In the embodiment of FIG. 5, the conductive frame 525 may include three different layers 535, 545, and 565. Each of the layers 535/545/565 may be formed of the same conductive material or a different conductive material from one another. Generally, the layers 535/545/565 may be electrically decoupled from one another such that signals propagating through one of the layers 535/545/565 may not propagate to another of the layers 535/545/565.

As can be seen, respective ones of the layers 535/545/565 may include fingers 527, 537, and 547 which may be similar to fingers 427. Each of the fingers 527/537/547 may be coupled with a respective one of the electrical interconnects 555 as seen in FIG. 5. In some embodiments fingers of one of the outer layers of the conductive frame 525, e.g. fingers 547 or 537 may be physically coupled with, but electrically decoupled from, an inner layer of the conductive frame which is overlapped by the finger. For example, fingers 537 may be physically coupled with, but electrically decoupled from, layer 565. In other embodiments, fingers such as finger 537 may not be physically coupled with a layer such as layer 565.

The various layers 535/545/565 may be electrically coupled with different ones of the rails of the substrate to which the semiconductor package 500 is coupled. For example, if the semiconductor package 500 is coupled with a substrate such as substrate 150, then different ones of the electrical interconnects 555 may be coupled with different ones of rails 160/165/170/175. In this case, dependent on which electrical interconnects 555 the various fingers 527/537/547 are coupled with, the various layers 535/545/565 may be coupled with different ones of the rails 160/165/170/175.

As a concrete example, if the semiconductor package 500 was coupled with a substrate such as substrate 150, then one of the electrical interconnects 555 may be coupled with a rail (e.g., rail 160) that is a first power rail (e.g., VCC1). Finger 527 may be coupled with that electrical interconnect, and therefore layer 565 may be communicatively coupled with VCC1. Similarly, one of the electrical interconnects 555 may be coupled with a rail (e.g., rail 170) that is a ground rail (e.g., VSS). Finger 537 may be coupled with that electrical interconnect, and therefore layer 535 may be communicatively coupled with VSS. Similarly, one of the electrical interconnects 555 may be coupled with a rail (e.g., rail 175) that is a second power rail (e.g., VCC2). Finger 547 may be coupled with that electrical interconnect, and therefore layer 545 may be communicatively coupled with VCC2.

It will, however, be understood that this description of the various layers and couplings is intended as one example and in other embodiments different ones of the layers 535/545/565 may be coupled with different rails of the substrate to which the semiconductor package 500 is coupled. Additionally, as noted above, the package 500 may include more or fewer layers than are depicted in FIG. 5. Similarly, the package 500 may include more or fewer electrical interconnects 555, as explained above with respect to FIG. 4. In some embodiments, the various layers 535/545/565 may include more or fewer fingers 527/537/547 than depicted in FIG. 5. Various ones of the fingers 527/537/547 may each be coupled with a single electrical interconnect 555 as depicted in FIG. 5, or one or more of the fingers 527/537/547 may be coupled with a plurality of the electrical interconnects 555. Other variations may be present in other embodiments.

In some embodiments, it may be desirable for the semiconductor package 500 to include some type of capacitors. The capacitors may be desirable as local decoupling to ensure power integrity performance of voltage rails such as CPU core, graphics, and multiple input/output (IO) domains. FIG. 5 depicts one example of how such embodiments may be coupled with semiconductor package 500. Specifically, a plurality of discrete capacitors 560 may be coupled with the conductive frame 525. Specifically, the capacitors 560 may be coupled with two adjacent layers of the conductive frame 525. As can be seen in FIG. 5, in some embodiments one or more of the capacitors 560 may be coupled with both layers 565 and 535. Other capacitors 560 may be coupled with both layers 535 and 545. By placing the capacitors 560 on the conductive frame 525, loop inductance of the capacitors 560 may be smaller than if the capacitors were placed on the substrate to which the semiconductor package 500 is coupled (e.g., substrate 150 of FIG. 1).

It will be understood that although the embodiment of FIG. 5 depicts the semiconductor package conductive frame 525 with capacitors 560 on the same side of the semiconductor package 500 as the electrical interconnects 555, this embodiment is intended as one example depiction. In other embodiments, the capacitors 560 may not be present on the same side of the semiconductor package 500 as the electrical interconnects 555, but rather may be on the opposite side of the conductive frame 525 than depicted in FIG. 5. For example, the capacitors 560 may be coupled with the conductive frame 525 at a side of the semiconductor package 500 that does not include the electrical interconnects 555. In some embodiments, the capacitors 560 may be present on both sides of conductive frame 525.

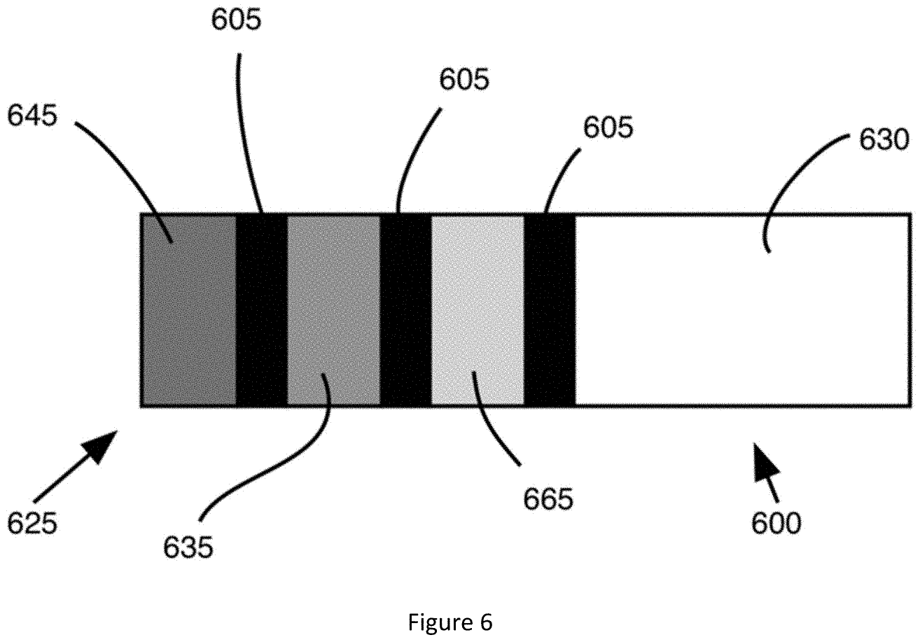

FIG. 6 depicts an alternative technique for introducing one or more capacitors to a semiconductor package such as semiconductor package 500. Specifically, FIG. 6 depicts a simplified cross-sectional view of a semiconductor package 600, which may be similar to semiconductor package 500. The semiconductor package 600 may include a conductive frame 625 coupled with a substrate 630, which may be respectively similar to conductive frame 525 and substrate 530. It will be understood that in embodiments the conductive frame 625 may at least partially overlap one or both of the top side and the bottom side of the substrate 630 (as oriented in FIG. 6), however such overlap is not depicted in FIG. 6 for the sake of lack of redundancy.

The conductive frame 625 may include a plurality of layers 635, 645, and 665, which may be respectively similar to layers 535, 545, and 565. The various layers 635/645/665 may have a dielectric material 605 positioned therebetween, and the dielectric material 605 may also be positioned between layer 665 and the substrate 630. In various embodiments, the dielectric material 605 may be a dielectric material with a relatively high permittivity value such as polymer film or some other material. More generally, the dielectric material 605 may be a material with a permittivity of greater than approximately 100. The dielectric material 605 may have a relative permittivity of greater than approximately 100. In some embodiments, the dielectric material 605 may be the same material positioned in between each of the various layers 635/645/665, while in other embodiments a different material (or the same material with a different relative permittivity) may be positioned between one or more of the layers from another location between one or more of the layers. In some embodiments certain of the dielectric materials 605 may not be present. For example, in some embodiments the dielectric material 605 may not be positioned between the substrate 630 and the layer 665. Generally, the dielectric material 605 may generate a high-frequency capacitance that may be desirable for load self-noise mitigation. In some embodiments, the dielectric material 605 may be used in place of, or in conjunction with, on-frame capacitors such as capacitors 560.

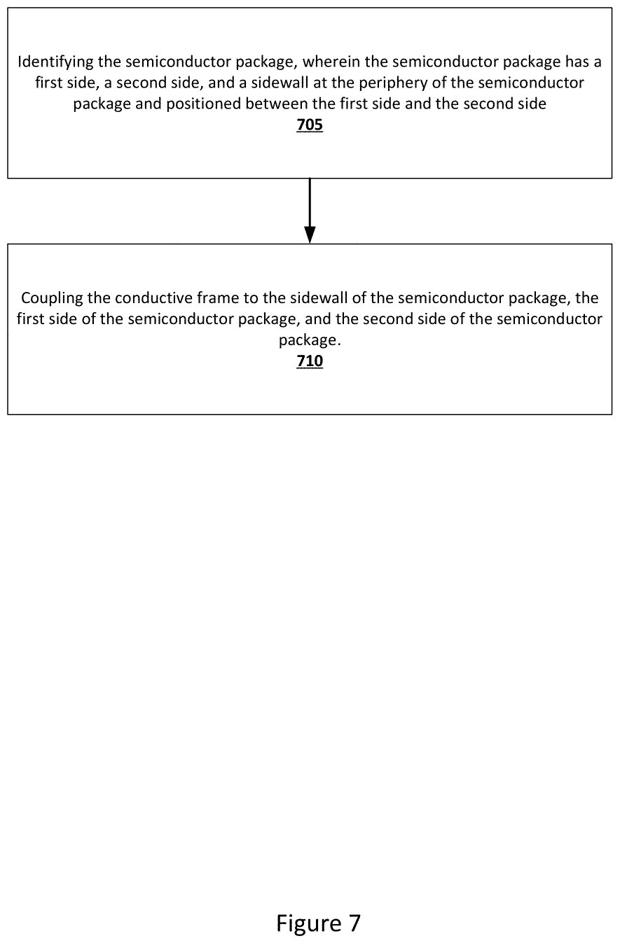

FIG. 7 depicts an example technique for the manufacture of a semiconductor package, in accordance with various embodiments. Specifically, the technique may include identifying, at 705, a semiconductor package. The semiconductor package may be similar to for example, the semiconductor package described above with respect to FIG. 1. For example, the semiconductor package may include substrate 130, dies 115/105, electrical interconnects 120/110, or one or more other elements described above with respect to FIG. 1. The semiconductor package may have a first side, a second side, and a sidewall at the periphery of the semiconductor package that is positioned between the first side and the second side. For example, the first side of the semiconductor package may be similar to the side of the substrate 130 to which the electrical interconnects 110 or 120 are coupled. The second side may be, for example, the side of the substrate 130 to which the electrical interconnects 155 are coupled. The sidewall may be, for example, the vertical portion of the substrate 130 depicted in FIG. 1 that is between the first side and the second side of the substrate 130.

The technique may further include coupling, at 710, a conductive frame to the sidewall of the semiconductor package. The conductive frame may be similar to, for example, conductive frame 125. In embodiments, the conductive frame may additionally be coupled to one or both of the first side and the second side of the semiconductor package. For example, as shown in FIG. 1, the conductive frame 125 may be coupled to both the first side and the second side of the substrate 130.

It will be understood that although the technique of FIG. 7 is described with respect to elements of FIG. 1, in other embodiments the technique may further be applied to various ones of the semiconductor package is described in, or referred to in, FIG. 2, 3, 4, 5, or 6.

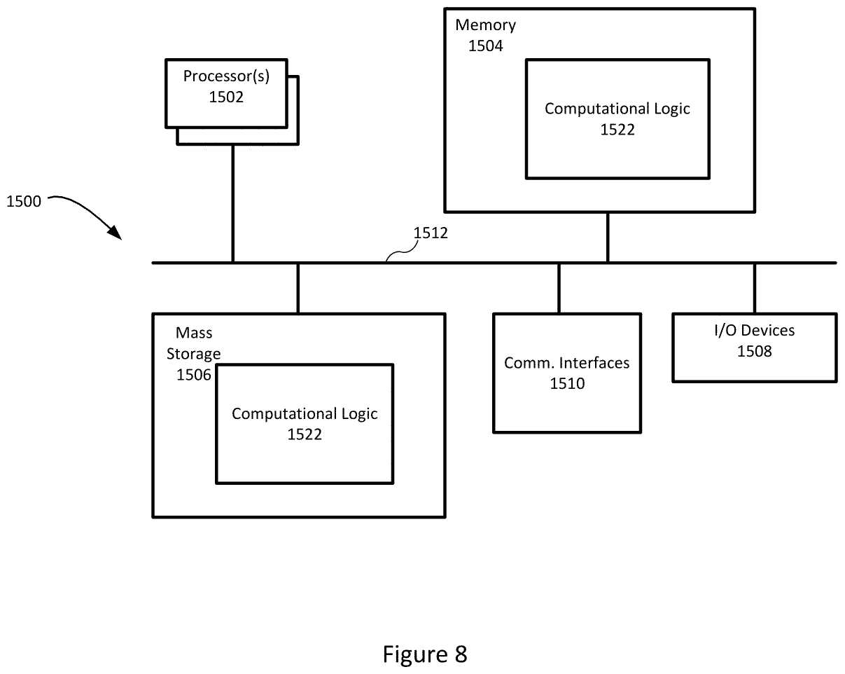

FIG. 8 illustrates an example computing device 1500 suitable for use with system 100 or semiconductor packages 200/300/400/500/600, in accordance with various embodiments. Specifically, in some embodiments, the computing device 1500 may include one or more of system 100 or packages 200/300/400/500/600 therein.

As shown, computing device 1500 may include one or more processors or processor cores 1502 and system memory 1504. For the purpose of this application, including the claims, the terms “processor” and “processor cores” may be considered synonymous, unless the context clearly requires otherwise. The processor 1502 may include any type of processors, such as a CPU, a microprocessor, and the like. The processor 1502 may be implemented as an integrated circuit having multi-cores, e.g., a multi-core microprocessor. The computing device 1500 may include mass storage devices 1506 (such as diskette, hard drive, volatile memory (e.g., DRAM, compact disc read-only memory (CD-ROM), digital versatile disk (DVD), and so forth)). In general, system memory 1504 and/or mass storage devices 1506 may be temporal and/or persistent storage of any type, including, but not limited to, volatile and NVM, optical, magnetic, and/or solid state mass storage, and so forth. Volatile memory may include, but is not limited to, static and/or DRAM. NVM may include, but is not limited to, electrically erasable programmable read-only memory, phase change memory, resistive memory, and so forth. In some embodiments, one or both of the system memory 1504 or the mass storage device 1506 may include computational logic 1522, which may be configured to implement or perform, in whole or in part, one or more instructions that may be stored in the system memory 1504 or the mass storage device 1506. In other embodiments, the computational logic 1522 may be configured to perform a memory-related command such as a read or write command on the system memory 1504 or the mass storage device 1506.

The computing device 1500 may further include input/output (I/O) devices 1508 (such as a display (e.g., a touchscreen display), keyboard, cursor control, remote control, gaming controller, image capture device, and so forth) and communication interfaces 1510 (such as network interface cards, modems, infrared receivers, radio receivers (e.g., Bluetooth), and so forth).

The communication interfaces 1510 may include communication chips (not shown) that may be configured to operate the device 1500 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 1510 may operate in accordance with other wireless protocols in other embodiments.

The computing device 1500 may further include or be coupled with a power supply. The power supply may, for example, be a power supply that is internal to the computing device 1500 such as a battery. In other embodiments the power supply may be external to the computing device 1500. For example, the power supply may be an electrical source such as an electrical outlet, an external battery, or some other type of power supply. The power supply may be, for example AC, direct current (DC) or some other type of power supply. The power supply may in some embodiments include one or more additional components such as an AC to DC convertor, one or more downconverters, one or more upconverters, transistors, resistors, capacitors, etc. that may be used, for example, to tune or alter the current or voltage of the power supply from one level to another level. In some embodiments the power supply may be configured to provide power to the computing device 1500 or one or more discrete components of the computing device 1500 such as the processor(s) 1502, mass storage 1506, I/O devices 1508, etc.

The above-described computing device 1500 elements may be coupled to each other via system bus 1512, which may represent one or more buses. In the case of multiple buses, they may be bridged by one or more bus bridges (not shown). Each of these elements may perform its conventional functions known in the art. The various elements may be implemented by assembler instructions supported by processor(s) 1502 or high-level languages that may be compiled into such instructions.

The permanent copy of the programming instructions may be placed into mass storage devices 1506 in the factory, or in the field, through, for example, a distribution medium (not shown), such as a compact disc (CD), or through communication interface 1510 (from a distribution server (not shown)). That is, one or more distribution media having an implementation of the agent program may be employed to distribute the agent and to program various computing devices.

The number, capability, and/or capacity of the elements 1508, 1510, 1512 may vary, depending on whether computing device 1500 is used as a stationary computing device, such as a set-top box or desktop computer, or a mobile computing device, such as a tablet computing device, laptop computer, game console, or smartphone. Their constitutions are otherwise known, and accordingly will not be further described.

In various implementations, the computing device 1500 may comprise one or more components of a data center, a laptop, a netbook, a notebook, an ultrabook, a smartphone, a tablet, a personal digital assistant (PDA), an ultra mobile PC, a mobile phone, or a digital camera. In further implementations, the computing device 1500 may be any other electronic device that processes data.

In some embodiments, as noted above, computing device 1500 may include one or more of system 100 or packages 200/300/400/500/600. For example, dies 105/115 may be an element such as processor 1502, memory 1504, etc. As noted above, various of packages such as packages 200/300/400/500/600 may include a die such as processor 1502, memory 1504, etc.

### EXAMPLES OF VARIOUS EMBODIMENTS

Example 1 includes an electronic device comprising: a semiconductor package with a first side and a second side opposite the first side, and a sidewall positioned between the first side and the second side at a perimeter of the semiconductor package; and a conductive frame that includes a first portion, a second portion, and a third portion positioned between the first portion and the second portion, wherein the first portion is coupled with the first side of the semiconductor package, the second portion is coupled with the second side of the semiconductor package, and the third portion is coupled with the sidewall of the semiconductor package.

Example 2 includes the electronic device of example 1, wherein the first portion has a width as measured in a direction parallel to the first side of the package of 500 micrometers.

Example 3 includes the electronic device of example 1, wherein the third portion has a width as measured in a direction parallel to the first side of the package of 200 micrometers.

Example 4 includes the electronic device of example 1, wherein the conductive frame includes copper.

Example 5 includes the electronic device of example 1, wherein at least part of the first surface and the second surface are exposed by the conductive frame.

Example 5.5 includes the electronic device of any of examples 1-5, wherein the conductive frame is electrically conductive.

Example 6 includes the electronic device of any of examples 1-5, wherein the first portion or the second portion are coupled with a power rail of the semiconductor package.

Example 7 includes the electronic device of example 6, wherein the first side of the package is to couple with a die, and wherein the first portion of the conductive frame is coupled with the power rail by a micro-via in the first side of the package.

Example 8 includes the electronic device of example 7, wherein the die is a memory or a processor.

Example 9 includes the electronic device of example 6, wherein the second side of the package is to couple with a substrate by an interconnect, and wherein the second portion of the conductive frame is coupled with the power rail by the interconnect.

Example 10 includes the electronic device of example 9, wherein the interconnect is a solder bump.

Example 11 includes the electronic device of example 6, wherein the power rail is a signal rail or a ground rail.

Example 12 includes the electronic device of any of examples 1-5, wherein the first side of the semiconductor package has a first plurality of interconnects at a first pitch, and the second side of the semiconductor package has a second plurality of interconnects at a second pitch that is different than the first pitch.

Example 13 includes a semiconductor package structure comprising: a semiconductor package with a first side and a second side opposite the first side, wherein the first side includes a plurality of interconnects configured to couple with a substrate; and a conductive frame coupled with the semiconductor package at the periphery of the semiconductor package, wherein the conductive frame includes: a first layer coupled with the conductive frame, wherein the first layer includes a first extension that is electrically and physically/mechanically coupled with a first interconnect of the plurality of interconnects; and a second layer coupled with the first layer such that the first layer is positioned between the semiconductor package and the second layer, wherein the second layer includes a second extension that is electrically and physically/mechanically coupled with a second interconnect of the plurality of interconnects.

Example 14 includes the semiconductor package structure of example 13, wherein the first side and the second side of the semiconductor package are exposed through the conductive frame.

Example 15 includes the semiconductor package structure of example 13, wherein the conductive frame further comprises a third layer coupled with the second layer such that the second layer is positioned between the first layer and the third layer, wherein the third layer includes a third extension that is electrically and physically/mechanically coupled with a third interconnect of the plurality of interconnects.

Example 16 includes the semiconductor package structure of example 15, wherein the third layer is coupled, by the third interconnect, with a power rail of the semiconductor package.

Example 17 includes the semiconductor package structure of example 13, wherein the first layer is coupled, by the first interconnect, with a power rail of the semiconductor package.

Example 18 includes the semiconductor package structure of example 13, wherein the second layer is coupled, by the second interconnect, with a ground rail of the semiconductor package.

Example 19 includes the semiconductor package structure of any of examples 13-16, wherein the conductive frame includes copper.

Example 20 includes the semiconductor package structure of any of examples 13-16, wherein the plurality of interconnects is a ball grid array (BGA).

Example 21 includes a semiconductor package structure comprising: a semiconductor package that includes: a first side with a first set of interconnects configured to couple with a substrate of a computing device; a second side with a second set of interconnects configured to couple with a die; and a sidewall positioned at a periphery of the semiconductor package between the first side and the second side; and a conductive frame coupled with the semiconductor package, wherein the conductive frame includes: a first layer coupled with the first side, the second side, and the sidewall; and a second layer coupled with the first layer.

Example 22 includes the semiconductor package structure of example 21, wherein the first layer is electrically coupled with a first power rail of the package, and the second layer is electrically coupled with a second power rail of the package.

Example 23 includes the semiconductor package structure of example 22, wherein the first layer is a power layer and the second layer is a ground layer.

Example 24 includes the semiconductor package structure of any of examples 21-23, wherein the conductive frame further comprises a third layer coupled with the second layer.

Example 25 includes the semiconductor package structure of any of examples 21-23, wherein the conductive frame further comprises a dielectric material with a dielectric constant with a relative permittivity greater than 100 positioned between the first layer and the second layer.

Example 26 includes the semiconductor package structure of any of examples 21-23, further comprising a capacitor coupled with the first layer and the second layer.

Example 27 includes the semiconductor package structure of any of examples 21-23, wherein the conductive frame includes copper.

Example 28 includes a method of forming a semiconductor package structure that includes a semiconductor package and a conductive frame at the periphery of the semiconductor package, the method comprising: identifying the semiconductor package, wherein the semiconductor package has a first side, a second side, and a sidewall at the periphery of the semiconductor package and positioned between the first side and the second side; and coupling the conductive frame to the sidewall of the semiconductor package, the first side of the semiconductor package, and the second side of the semiconductor package.

Example 29 includes the method of example 28, wherein the conductive frame includes a first layer coupled with the semiconductor package and a second layer coupled with the first layer such that the first layer is positioned between the semiconductor package and the second layer.

Example 30 includes the method of example 28, wherein the conductive frame further comprises a third layer coupled with the second layer such that the second layer is between the first layer and the third layer.

Example 31 includes the method of any of examples 28-30, further comprising coupling the conductive frame with a power rail of the semiconductor package.

Example 32 includes the method of example 31, wherein the power rail is a signal rail or a ground rail.

Example 33 includes the method of example 31, wherein coupling the conductive frame with the power rail includes coupling the conductive frame, at the first side of the package, with a micro-via that is communicatively coupled with the power rail.

Example 34 includes the method of example 31, wherein coupling the conductive frame with the power rail includes coupling the conductive frame, at the second side of the package, with an interconnect that is communicatively coupled with the power rail.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. An electronic device comprising:
a semiconductor package with a first side and a second side opposite the first side, and a sidewall positioned between the first side and the second side at a perimeter of the semiconductor package; and
a conductive frame that includes a first portion, a second portion, and a third portion positioned between the first portion and the second portion, wherein the first portion is coupled with the first side of the semiconductor package, the second portion is coupled with the second side of the semiconductor package, and the third portion is coupled with the sidewall of the semiconductor package.

2. The electronic device of claim 1, wherein the first portion has a width of 500 micrometers, as measured in a direction parallel to the first side of the package.

3. The electronic device of claim 1, wherein the third portion has a width of 200 micrometers, as measured in a direction parallel to the first side of the package.

4. The electronic device of claim 1, wherein at least part of the first side and the second side are exposed by an opening in the conductive frame.

5. The electronic device of claim 1, wherein the first portion or the second portion are coupled with a power rail of the semiconductor package.

6. The electronic device of claim 1, wherein the first side of the semiconductor package has a first plurality of interconnects at a first pitch, and the second side of the semiconductor package has a second plurality of interconnects at a second pitch that is different than the first pitch.

7. A semiconductor package structure comprising:
a semiconductor package with a first side and a second side opposite the first side, wherein the first side includes a plurality of interconnects that are to couple with a substrate; and
a conductive frame coupled with the semiconductor package at a periphery of the semiconductor package, wherein the conductive frame includes:
a first layer coupled with the conductive frame, wherein the first layer includes a first extension that is electrically and physically coupled with a first interconnect of the plurality of interconnects; and
a second layer coupled with the first layer such that the first layer is positioned between the semiconductor package and the second layer, wherein the second layer includes a second extension that is electrically and physically coupled with a second interconnect of the plurality of interconnects.

8. The semiconductor package structure of claim 7, wherein the first side and the second side of the semiconductor package are exposed through the conductive frame.

9. The semiconductor package structure of claim 7, wherein the conductive frame further includes a third layer coupled with the second layer such that the second layer is positioned between the first layer and the third layer, wherein the third layer includes a third extension that is electrically and physically coupled with a third interconnect of the plurality of interconnects.

10. The semiconductor package structure of claim 7, wherein the first layer is coupled, by the first interconnect, with a power rail of the semiconductor package.

11. The semiconductor package structure of claim 7, wherein the second layer is coupled, by the second interconnect, with a ground rail of the semiconductor package.

12. The semiconductor package structure of claim 7, wherein the conductive frame includes copper.

13. The semiconductor package structure of claim 7, wherein the plurality of interconnects is a ball grid array (BGA).

14. A semiconductor package structure comprising:
a semiconductor package that includes:
a first side with a first set of interconnects that are to couple with a substrate of a computing device;
a second side with a second set of interconnects that are to couple with a die; and
a sidewall positioned at a periphery of the semiconductor package between the first side and the second side; and
a conductive frame coupled with the semiconductor package, wherein the conductive frame includes:
a first layer coupled with the first side, the second side, and the sidewall; and
a second layer coupled with the first layer.

15. The semiconductor package structure of claim 14, wherein the first layer is electrically coupled with a first power rail of the package, and the second layer is electrically coupled with a second power rail of the package.

16. The semiconductor package structure of claim 14, wherein the conductive frame further comprises a third layer coupled with the second layer.

17. The semiconductor package structure of claim 14, wherein the conductive frame further comprises a dielectric material with a relative permittivity greater than 100, the dielectric material positioned between the first layer and the second layer.

18. The semiconductor package structure of claim 14, further comprising a capacitor coupled with the first layer and the second layer.

19. The semiconductor package structure of claim 14, wherein the conductive frame includes copper.

20. A method of forming a semiconductor package structure that includes a semiconductor package and a conductive frame at a periphery of the semiconductor package, the method comprising:
identifying the semiconductor package, wherein the semiconductor package has a first side, a second side, and a sidewall at the periphery of the semiconductor package and positioned between the first side and the second side; and
coupling the conductive frame to the sidewall of the semiconductor package, the first side of the semiconductor package, and the second side of the semiconductor package.

21. The method of claim 20, wherein the conductive frame includes a first layer coupled with the semiconductor package and a second layer coupled with the first layer such that the first layer is positioned between the semiconductor package and the second layer.

22. The method of claim 20, further comprising coupling the conductive frame with a power rail of the semiconductor package.

23. The method of claim 22, wherein the power rail is a signal rail or a ground rail.

24. The method of claim 22, wherein coupling the conductive frame with the power rail includes coupling the conductive frame, at the first side of the package, with a micro-via that is communicatively coupled with the power rail.

25. The method of claim 22, wherein coupling the conductive frame with the power rail includes coupling the conductive frame, at the second side of the package, with an interconnect that is communicatively coupled with the power rail.
